(19) United States
(12) Patent Application Publication
(10) Pub. No.: US 2007/0252653 A1
(43) Pub. Date: Nov. 1, 2007

(54) Oscillation Controlling Apparatus, Recording Medium Having Program Recorded Thereon, and Channel Selecting Apparatus

(75) Inventor: Youji Takei, Kumagaya-shi (JP)

Correspondence Address: SoCAL IP LAW GROUP LLP, 310 N. WESTLAKE BLVD. STE 120, WESTLAKE VILLAGE, CA, 91362, US

(73) Assignee: Sanyo Electric Co., Ltd., Osaka (JP)

(21) Appl. No.: 11/734,759

(22) Filed: Apr. 12, 2007

(30) Foreign Application Priority Data
Apr. 13, 2006 (JP) 2006-110880

(51) Int. Cl. H03L 7/00

(52) U.S. Cl. 331/16

(57) ABSTRACT

An oscillation controlling apparatus configured to control an oscillation frequency of an oscillation circuit to be a target frequency comprises a frequency acquiring unit configured to acquire a plurality of oscillation frequencies of the oscillation circuit for a plurality of values of control signals by outputting the plurality of control signals increasing or decreasing the oscillation frequency of the oscillation circuit as values thereof are increased or decreased; a frequency characteristic calculating unit configured to calculate data indicating a relationship between the plurality of oscillation frequencies and the plurality of values of the control signals with a least-square method, based on the plurality of values of the control signals output by the frequency acquiring unit and the plurality of oscillation frequencies acquired by the frequency acquiring unit; and a control signal output unit configured to output the control signal setting the oscillation frequency to the target frequency, based on the data calculated by the frequency characteristic calculating unit.

### CROSS-REFERENCE TO RELATED APPLICATION

This application claims the benefit of priority to Japanese Patent Application No. 2006-110880, filed Apr. 13, 2006, of which full contents are incorporated herein by reference.

### BACKGROUND OF THE INVENTION

1. Field of the Invention

The present invention relates to an oscillation controlling apparatus, a recording medium having a program recorded thereon, and a channel selecting apparatus.

2. Description of the Related Art

In FM radio receivers, AM radio receivers, etc., oscillation circuits are used to extract signals of desired broadcast stations from received signals and to convert received signals into intermediate frequency signals. Such an oscillation circuit includes a coil, a capacitor, and a varicap (variable-capacitance diode), for example. Capacitances of the capacitor and varicap are changed in accordance with a value of a control signal input from a microcomputer, etc., and the oscillation frequency of the oscillation circuit is changed into a target frequency to extract a signal of a desired broadcast station and to convert a signal into an intermediate frequency signal (e.g., Japanese Patent Application Laid-Open Publication No. 2002-111527).

In the oscillation circuit changing capacitances of the capacitor, varicap, etc., to adjust an oscillation frequency, due to effects of temperature characteristics and manufacturing variances, the value of the control signal cannot be set in advance to set the oscillation frequency to the target frequency. Therefore, the value of the control signal must be obtained to set the oscillation frequency to the target frequency at the timing of changing the oscillation frequency.

In one method of obtaining the value of the control signal corresponding to the target frequency, the value of the control signal is changed stepwise within a variable range to obtain the value of the control signal setting the oscillation frequency to the target frequency.

However, since the value of the control signal is changed stepwise in this method, it takes very long time to obtain the value of the control signal corresponding to the target frequency.

In another method of obtaining the value of the control signal corresponding to the target frequency, linear approximation is used. In the method using linear approximation, an approximate line showing the frequency characteristic of the oscillation frequency is obtained based on oscillation frequencies of two appropriate values of the control signal. An approximate value of the control signal corresponding to the target frequency is obtained in accordance with this approximate line. The value of the control signal is then changed near the approximate value to obtain the control signal corresponding to the target frequency.

However, the characteristic of the oscillation frequency in the oscillation circuit is a curve such as a quadratic curve, and the approximate value of the control signal obtained from the approximate line may differ greatly from the value of the control signal corresponding to the target frequency. Therefore, a large range must be defined for changing the control signal near the approximate value of the control signal, and it takes long time to obtain the value of the control signal corresponding to the target frequency.

### SUMMARY OF THE INVENTION

The present invention was conceived in view of the above problems and it is therefore the object of the present invention to provide an oscillation controlling apparatus, recording medium having program recorded thereon, and channel selecting apparatus which are able to set the oscillation frequency to the target frequency quickly.

In order to achieve the above object, according to an aspect of the present invention there is provided an oscillation controlling apparatus configured to control an oscillation frequency of an oscillation circuit to be a target frequency, comprising: a frequency acquiring unit configured to acquire a plurality of oscillation frequencies of the oscillation circuit for a plurality of values of control signals by outputting the plurality of control signals increasing or decreasing the oscillation frequency of the oscillation circuit as values thereof are increased or decreased; a frequency characteristic calculating unit configured to calculate data indicating a relationship between the plurality of oscillation frequencies and the plurality of values of the control signals with a least-square method, based on the plurality of values of the control signals output by the frequency acquiring unit and the plurality of oscillation frequencies acquired by the frequency acquiring unit; and a control signal output unit configured to output the control signal setting the oscillation frequency to the target frequency, based on the data calculated by the frequency characteristic calculating unit. Other features of the present invention will become apparent from descriptions of this specification and of the accompanying drawings.

### BRIEF DESCRIPTION OF THE DRAWINGS

For more thorough understanding of the present invention and advantages thereof, the following description should be read in conjunction with the accompanying drawings, in which: FIG. 1 is a diagram of a configuration example of an FM radio receiver that is an embodiment of the present invention.

FIG. 2 is a diagram of a configuration example of a high-frequency tuning circuit.

FIG. 3 is a diagram of a configuration example of a local oscillation circuit.

FIG. 4 is a diagram of a configuration example of an oscillation circuit.

FIG. 5 is a diagram of a configuration of a functional block realized by a microcomputer.

FIG. 6 is a diagram of an example of an approximate curve showing a frequency characteristic of an oscillation frequency in the high-frequency tuning circuit.

FIG. 7 is a flowchart of a control signal determining process.

### DETAILED DESCRIPTION OF THE INVENTION

At least the following details will become apparent from descriptions of this specification and of the accompanying drawings.

==Overall Configuration==

FIG. 1 is a diagram of a configuration example of an FM radio receiver that is an embodiment of the present invention. An FM radio receiver 1 includes an antenna 10, a high-frequency tuning circuit 11, a high-frequency amplification circuit 12, a local oscillation circuit 13, a mixing circuit 14, an intermediate frequency amplification circuit 15, a detection circuit 16, a pilot detection circuit 17, an oscillation circuit 18, a stereo demodulation circuit 19, low-frequency amplification circuits 20L, 20R, speakers 21L, 21R, a switch circuit 24, a counter 25, an operating unit 26, and a microcomputer 27. The FM radio receiver 1 corresponds to a channel selecting apparatus of the present invention, and the microcomputer 27 corresponds to an oscillation controlling apparatus of the present invention.

The high-frequency tuning circuit 11 performs tuning operation to extract a reception signal having a desired reception frequency fr from FM reception signals input to the antenna 10. The high-frequency tuning circuit 11 controls a tuning frequency to be fr based on a control signal input from the microcomputer 27. The high-frequency amplification circuit 12 amplifies and outputs the signal having the reception frequency output from the high-frequency tuning circuit 11.

The local oscillation circuit 13 outputs a local oscillation signal having a frequency higher than the reception frequency fr by a predetermined intermediate frequency fi (e.g., 10.7 MHz). The local oscillation circuit 13 controls the frequency of the local oscillation signal to be fr+fi based on the control signal input from the microcomputer 27.

The mixing circuit 14 mixes the reception signal having the frequency fr output from the high-frequency amplification circuit 12 and the local oscillation signal having the frequency fr+fi output from the local oscillation circuit 13 to output a signal corresponding to a difference component. The intermediate frequency amplification circuit 15 amplifies the signal output from the mixing circuit 14 and allows passage of only a frequency component near the predetermined intermediate frequency fi to generate an intermediate frequency signal.

The detection circuit 16 performs a detection process for the intermediate frequency signal output from the intermediate frequency amplification circuit 15 to convert the signal into a stereo composite signal. The stereo composite signal is synthesized from an L-signal (left audio signal) component, an R-signal (right audio signal) component, and, for example, a 19-kHz pilot signal.

The pilot detection circuit 17 detects the frequency of the pilot signal included in the stereo composite signal output from the detection circuit 16. The frequency of the pilot signal is detected by the pilot detection circuit 17 and input to the microcomputer 27.

The oscillation circuit 18 outputs a signal having a frequency (e.g., 456 kHz obtained by multiplying 19 kHz by 24) corresponding to the frequency (e.g., 19 kHz) of the pilot signal. The oscillation circuit 18 performs control to generate the oscillation frequency corresponding to the frequency of the pilot signal based on the control signal input from the microcomputer 27.

From the signal output from the oscillation circuit 18 and having the frequency (e.g., 456 kHz) corresponding to the frequency of the pilot signal, the stereo demodulation circuit 19 generates a subcarrier signal having a frequency (e.g., 38 kHz) obtained by doubling the frequency of the pilot signal, for example. The stereo demodulation circuit 19 loads the stereo composite signal output from the detection circuit 16 in synchronization with the subcarrier signal to pick up and output the L-signal and the R-signal from the stereo composite signal.

The low-frequency amplification circuit 20L amplifies the L-signal output from the stereo demodulation circuit 19 and outputs the L-signal to the speaker 21L. The low-frequency amplification circuit 20R amplifies the R-signal output from the stereo demodulation circuit 19 and outputs the R-signal to the speaker 21R.

Under the control of the microcomputer 27, the switch circuit 24 selects a signal output from any one of the high-frequency tuning circuit 11, the local oscillation circuit 13, and the oscillation circuit 18 and outputs the signal to the counter 25. The counter 25 counts and outputs a number of times of oscillation of an input signal within a predetermined time.

The operating unit 26 is used by a user for selecting a desired reception frequency and is, for example, a dial-type or button-type frequency input apparatus.

The microcomputer 27 outputs a control signal for controlling the oscillation frequencies of the high-frequency tuning circuit 11, the local oscillation circuit 13, and the oscillation circuit 18. When controlling the oscillation frequency of the high-frequency tuning circuit 11, the microcomputer 27 switches the switch circuit 24 toward the high-frequency tuning circuit 11 and acquires the output of the counter 25. The microcomputer 27 changes and outputs the control signal to the high-frequency tuning circuit 11 such that the counted number output from the counter 25 becomes a counted number indicating the reception frequency selected by the operating unit 26. When controlling the oscillation frequency of the local oscillation circuit 13, the microcomputer 27 switches the switch circuit 24 toward the local oscillation circuit 13 and acquires the output of the counter 25. The microcomputer 27 changes and outputs the control signal to the local oscillation circuit 13 such that the counted number output from the counter 25 becomes a counted number indicating a frequency obtained by adding the intermediate frequency to the reception frequency selected by the operating unit 26. When controlling the oscillation frequency of the oscillation circuit 18, the microcomputer 27 switches the switch circuit 24 toward the oscillation circuit 18 and acquires the output of the counter 25. The microcomputer 27 changes and outputs the control signal to the oscillation circuit 18 such that the counted number output from the counter 25 becomes a counted number indicating a frequency (e.g., 456 kHz) corresponding to the frequency of the pilot signal.

==Detailed Configuration==

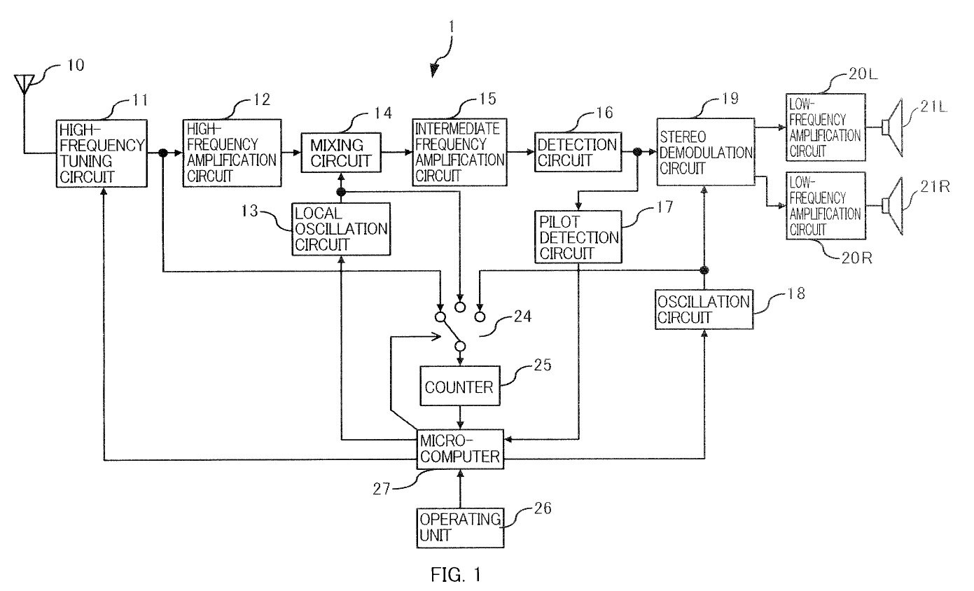

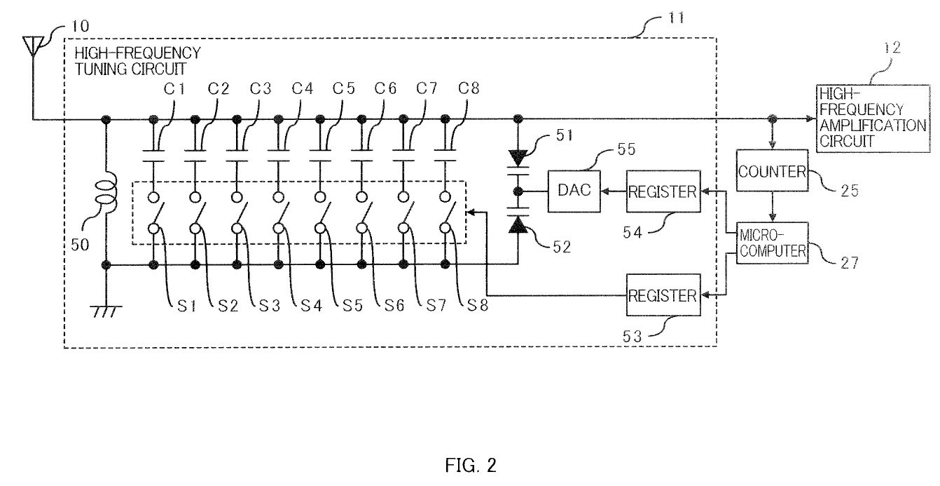

Detailed configurations of the high-frequency tuning circuit 11, the local oscillation circuit 13, and the oscillation circuit 18 will be described. FIG. 2 is a diagram of a configuration example of the high-frequency tuning circuit 11. The high-frequency tuning circuit 11 includes an inductor 50, capacitors C1 to C8, switch circuits S1 to S8, varicaps (variable-capacitance diodes) 51, 52, registers 53, 54, and a DA converter (DAC) 55. The high-frequency tuning circuit 11 is a tuning circuit with the inductor 50, the capacitors C1 to C8, and the varicaps 51, 52 connected in parallel and can adjust a tuning frequency with changes in capacitances of the capacitors and changes in capacitances of the varicaps 51, 52 due to turning on/off of the switch circuits S1 to S8.

The registers 53, 54 are, for example, eight-bit storage circuits and store the control signal output from the microcomputer 27. In this embodiment, the control signal is eight bits.

The switch circuits S1 to S8 are turned on/off in accordance with a value of each bit of the control signal output from the register 53. In this embodiment, each one of the switch circuits S1 to S8 is turned on if corresponding bit of the control signal is “0” and is turned off if corresponding bit of the control signal is “1”.

Therefore, for example, if the control signal is 0×00 (0× indicates hexadecimal expression), all the switch circuits S1 to S8 are turned on; if the control signal is 0×01, only the switch circuit S8 is turned off and the switch circuits S1 to S7 are turned on; and if the control signal is 0×FF, all the switch circuits S1 to S8 are turned off.

In the high-frequency tuning circuit 11, when all the switch circuits S1 to S8 are turned on, the composite capacitance of the capacitors C1 to C8 is maximized and the tuning frequency is minimized. When all the switch circuits S1 to S8 are turned off, the composite capacitance of the capacitors C1 to C8 is minimized and the tuning frequency is maximized. The variable range of the tuning frequency due to turning on/off of the switch circuits S1 to S8 can be on the order of 75 MHz to 110 MHz, for example.

The DAC 55 changes the control signal output from the register 54 into a reverse bias voltage, which is output and applied to the varicaps 51, 52. If the voltage output from the DAC 55 is decreased, the capacitances of the varicaps 51, 52 are increased and the tuning frequency is decreased. On the other hand, if the voltage output from the DAC 55 is increased, the capacitances of the varicaps 51, 52 are decreased and the tuning frequency is increased.

In an embodiment, the voltage output from the DAC 55 changes in proportion to the control signal output from the register 54. Therefore, the tuning frequency is decreased as the value of the control signal is decreased, and the tuning frequency is increased as the value of the control signal is increased. The variable width of the tuning frequency due to the changes in capacitances of the varicaps 51, 52 can be on the order of 1 MHz.

In this high-frequency tuning circuit 11, under the control of the microcomputer 27, the control signal set in the register 53 is adjusted to drive the tuning frequency to the vicinity of the desired reception frequency. Under the control of the microcomputer 27, the control signal set in the register 54 is then adjusted to set the tuning frequency to the reception frequency. For example, if the desired reception frequency is 80.0 MHz, the tuning frequency is adjusted on the order of 79.5 MHz to 80.5 MHz by the control signal set in the register 53 and the tuning frequency is finely adjusted to become 80.0 MHz by the control signal set in the register 54.

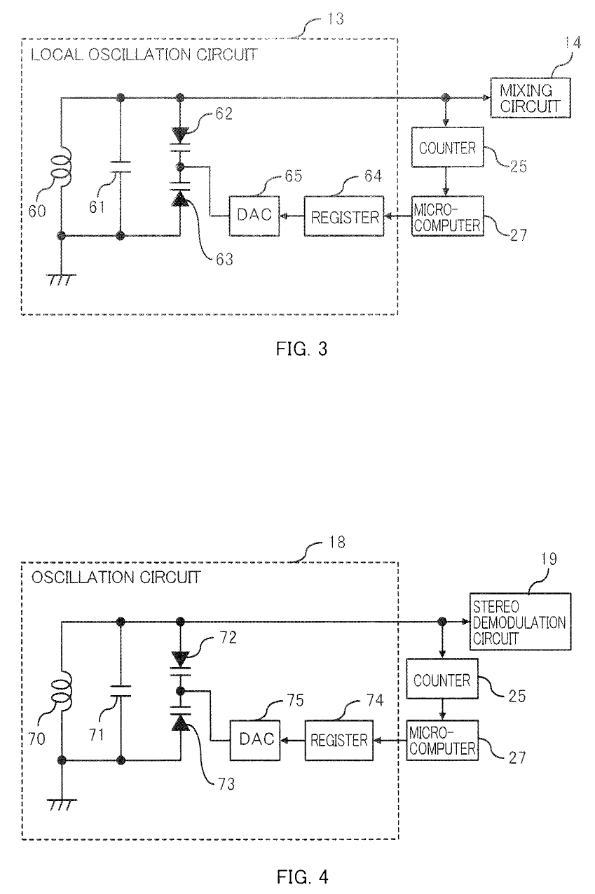

FIG. 3 is a diagram of a configuration example of the local oscillation circuit 13. The local oscillation circuit 13 includes an inductor 60, a capacitor 61, varicaps 62, 63, a register 64, and a DAC 65. The local oscillation circuit 13 is a tuning circuit with the inductor 60, the capacitor 61, and the varicaps 62, 63 connected in parallel and can adjust an oscillation frequency with changes in capacitances of the varicaps 62, 63.

The register 64 is, for example, eight-bit storage circuits and stores the control signal output from the microcomputer 27.

The DAC 65 changes the control signal output from the register 64 into a reverse bias voltage, which is output and applied to the varicaps 62, 63. If the voltage output from the DAC 65 is decreased, the capacitances of the varicaps 62, 63 are increased and the oscillation frequency is decreased. On the other hand, if the voltage output from the DAC 65 is increased, the capacitances of the varicaps 62, 63 are decreased and the oscillation frequency is increased.

In an embodiment, the voltage output from the DAC 65 changes in proportion to the control signal output from the register 64. Therefore, the oscillation frequency is decreased as the value of the control signal is decreased, and the oscillation frequency is increased as the value of the control signal is increased.

FIG. 4 is a diagram of a configuration example of the oscillation circuit 18. The oscillation circuit 18 includes an inductor 70, a capacitor 71, varicaps 72, 73, a register 74, and a DAC 75. Details of the units 70 to 75 are the same as the units 60 to 64 of the local oscillation circuit 13.

The local oscillation circuit 13 and the oscillation circuit 18 can also be configured such that the capacitances of the capacitors 61, 71 are changed in accordance with the control signal as is the case with the high-frequency tuning circuit 11.

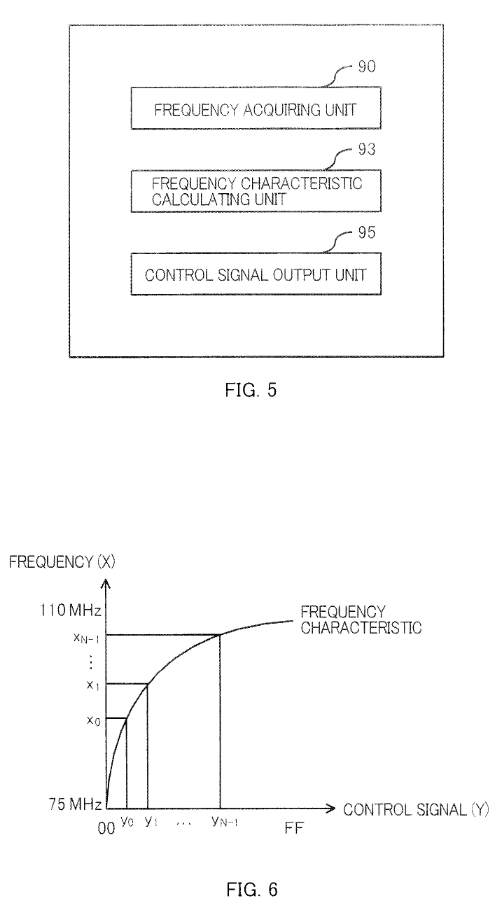

FIG. 5 is a diagram of a configuration of a functional block realized by the microcomputer 27. The microcomputer 27 includes a frequency acquiring unit 90, a frequency characteristic calculating unit 93, and a control signal output unit 95. The units 90, 93, 95 are realized by executing programs stored in a memory such as ROM (Read Only Memory) in the microcomputer 27 with a processor (not shown) in the microcomputer 27.

The frequency acquiring unit 90 outputs the control signals having a plurality of values to acquire the oscillation frequency of the high-frequency tuning circuit 11, the local oscillation circuit 13, or the oscillation circuit 18 at each value.

The frequency characteristic calculating unit 93 calculates data indicating a relationship between the oscillation frequencies and the values of the control signals in the high-frequency tuning circuit 11, the local oscillation circuit 13, or the oscillation circuit 18 with a least-square method, based on the plurality of values of the control signals output from the frequency acquiring unit 90 and a plurality of the oscillation frequencies acquired by the frequency acquiring unit 90.

The control signal output unit 95 outputs the control signal setting the oscillation frequency to the target frequency to the high-frequency tuning circuit 11, the local oscillation circuit 13, or the oscillation circuit 18, based on the data calculated by the frequency characteristic calculating unit 93

==Description of Operation==

Operation of adjusting the oscillation frequency in the FM radio receiver 1 will be described. First, an outline of a process of determining the control signal will be described with an example when an approximate curve showing the frequency characteristic of the oscillation frequency in the high-frequency tuning circuit 11 is a quadratic curve.

FIG. 6 is a diagram of an example of an approximate curve showing the frequency characteristic of the oscillation frequency in the high-frequency tuning circuit 11. In this embodiment, the control signal is eight bits; the oscillation frequency is about 75 MHz when the control signal is minimum (0×00); and the oscillation frequency is about 110 MHz when the control signal is maximum (0×FF). The approximate curve showing the frequency characteristic of the high-frequency tuning circuit 11 is a quadratic curve. That is, assuming that the oscillation frequency shown on the vertical axis is x and that the control signal shown on the horizontal axis is y, y=f(x)=c₀+c₁x+c₂x² is satisfied.

As shown in FIG. 6, the frequency acquiring unit 90 outputs N control signals y0, y₀, y₁, . . . y_{N-1} to the register 53 of the high-frequency tuning circuit 11 and acquires oscillation frequencies y₀, y₁, . . . y_{N-1} at those times. The frequency characteristic calculating unit 93 obtains coefficients c₀, c₁, and c₂ with a least-square method based on (xₙ, yₙ) <n=0 to N-1> acquired by the frequency acquiring unit 90. Specifically, the frequency characteristic calculating unit 93 obtains the coefficients c₀, c₁, and c₂ with the use of a square error S shown by the following equation.

$$S = {\sum }_{n = 0}^{N - 1} {( {y}_{n} - f ( {x}_{n} ) )}^{2} \qquad ( 1 )$$

An error Sₙ of (xₙ, yₙ) is Sₙ=(yₙ−c₀−c₁xₙ−c₂xₙ²)². Since partial differentiation is zero at the minimum points of c₀, c₁, and c₂, dS/dc₀=0, dS/dc₁=0, and dS/dc₂=0 are established. Therefore, the following equations (2) to (4) are satisfied.

$$\begin{matrix}{\sum }_{n = 0}^{N - 1} ( {y}_{n} - {c}_{0} - {c}_{1} {x}_{n} - {c}_{2} {x}_{n}^{2} ) & ( 2 ) \\ {\sum }_{n = 0}^{N - 1} ( {y}_{n} - {c}_{0} - {c}_{1} {x}_{n} - {c}_{2} {x}_{n}^{2} ) {x}_{n} & ( 3 ) \\ {\sum }_{n = 0}^{N - 1} ( {y}_{n} - {c}_{0} - {c}_{1} {x}_{n} - {c}_{2} {x}_{n}^{2} ) {x}_{n}^{2} & ( 4 )\end{matrix}$$

The following equations (5) to (7) are derived from the equations (2) to (4).

$$\begin{matrix}{c}_{0} N + {c}_{1} {\sum }_{n = 0}^{N - 1} {x}_{n} + {c}_{2} {\sum }_{n = 0}^{N - 1} {x}_{n}^{2} = {\sum }_{n = 0}^{N - 1} {y}_{n} & ( 5 ) \\ {c}_{0} {\sum }_{n = 0}^{N - 1} {x}_{n} + {c}_{1} {\sum }_{n = 0}^{N - 1} {x}_{n}^{2} + {c}_{2} {\sum }_{n = 0}^{N - 1} {x}_{n}^{3} = {\sum }_{n = 0}^{N - 1} {x}_{n} {y}_{n} & ( 6 ) \\ {c}_{0} {\sum }_{n = 0}^{N - 1} {x}_{n}^{2} + {c}_{1} {\sum }_{n = 0}^{N - 1} {x}_{n}^{3} + {c}_{2} {\sum }_{n = 0}^{N - 1} {x}_{n}^{4} = {\sum }_{n = 0}^{N - 1} {x}_{n}^{2} {y}_{n} & ( 7 )\end{matrix}$$

The equations (5) to (7) can be represented by the following equation (8) with a matrix.

$$( \begin{matrix}N & {\sum }_{n = 0}^{N - 1} {x}_{n} & {\sum }_{n = 0}^{N - 1} {x}_{n}^{2} \\ {\sum }_{n = 0}^{N - 1} {x}_{n} & {\sum }_{n = 0}^{N - 1} {x}_{n}^{2} & {\sum }_{n = 0}^{N - 1} {x}_{n}^{3} \\ {\sum }_{n = 0}^{N - 1} {x}_{n}^{2} & {\sum }_{n = 0}^{N - 1} {x}_{n}^{3} & {\sum }_{n = 0}^{N - 1} {x}_{n}^{4}\end{matrix} ) ( \begin{matrix}{c}_{0} \\ {c}_{1} \\ {c}_{2}\end{matrix} ) = ( \begin{matrix}{\sum }_{n = 0}^{N - 1} {y}_{n} \\ {\sum }_{n = 0}^{N - 1} {x}_{n} {y}_{n} \\ {\sum }_{n = 0}^{N - 1} {x}_{n}^{2} {y}_{n}\end{matrix} ) \qquad ( 8 )$$

That is, the frequency characteristic calculating unit 93 can calculate the coefficients c₀, c₁, and c₂ based on the equation (8).

When the coefficients c₀, c₁, and c₂ are calculated by the frequency characteristic calculating unit 93, the control signal output unit 95 substitutes a desired reception frequency (target frequency) into f(x) to obtain the control signal corresponding to the reception frequency. The control signal output unit 95 outputs the obtained control signal to the register 53 of the high-frequency tuning circuit 11. The same procedure can be used to obtain the control signals output to the register 54 of the high-frequency tuning circuit 11, the register 64 of the local oscillation circuit 13, and the register 74 of the oscillation circuit 18.

Although description has been made of an example when the order of the approximate curve of the frequency characteristic is the second order, if the order of the approximate curve is the mth order, the equation (8) can be represented by (A_{i,j})(cᵢ)=(Bᵢ) <i=0, 1, . . . m; j=0, 1, . . . m>. A_{i,j} and Bᵢ are represented by the following equations (9) and (10).

$$\begin{matrix}{A}_{i , j} = {\sum }_{n = 0}^{N - 1} {x}_{n}^{i + j} & ( 9 ) \\ {B}_{i} = {\sum }_{n = 0}^{N - 1} {x}_{n}^{i} {y}_{n} & ( 10 )\end{matrix}$$

From (A_{i,j})(cᵢ)=(Bᵢ), cᵢ can be obtained and substituted into f(x) to determine the value of the control signal corresponding to the target frequency.

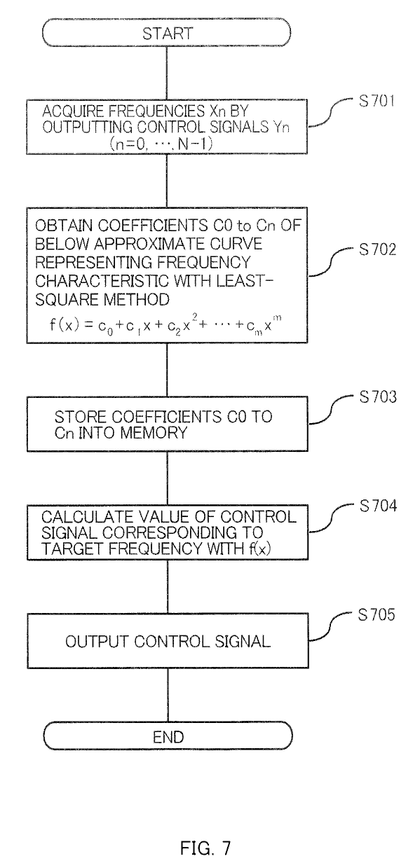

Details of the control signal determining process will be described with reference to a flowchart. FIG. 7 is a flowchart of the control signal determining process. An example of determining the control signal output to the register 53 of the high-frequency tuning circuit 11 will be described here.

When the reception frequency is input from the operating unit 26, the frequency acquiring unit 90 outputs N control signals yₙ (n=0, 1, . . . N-1) to the register 53 of the high-frequency tuning circuit 11 and acquires tuning frequencies xₙ corresponding to the control signals yₙ based on a counted number output from the counter 25 (S701).

The frequency characteristic calculating unit 93 obtains the coefficients c₀ to cₘ (first data) of the mth approximate curve representing the frequency characteristic of the high-frequency tuning circuit 11 with the above least-square method (S702) and store the coefficients c₀ to cₘ into a writable memory such as RAM (Random Access Memory) included in the microcomputer 27 (S703).

The control signal output unit 95 substitutes the reception frequency (target frequency) into f(x) determined by the coefficients c₀ to cₘ stored in the memory to calculate the value of the control signal corresponding to the reception frequency (S704) and outputs the calculated value of the control signal to the register 53 of the high-frequency tuning circuit 11 (S705).

The coefficients c₀ to cₘ (first data) are also calculated for the register 54 of the high-frequency tuning circuit 11 by the above process (S701 and S702), and the control signal corresponding to the target frequency is output based on the calculated coefficients c₀ to cₘ. Similarly, the coefficients c₀ to cₘ (second data) are also calculated for the register 64 of the local oscillation circuit 13 by the above process (S701 and S702), and the control signal corresponding to the target frequency is output based on the calculated coefficients c₀ to cₘ. Similarly, the coefficients c₀ to cₘ (third data) are also calculated for the register 74 of the oscillation circuit 18 by the above process (S701 and S702), and the control signal corresponding to the target frequency is output based on the calculated coefficients c₀ to cₘ.

Every time the target frequency is changed, the process of obtaining the coefficients c₀ to cₘ (S701 to S703) can be performed to reduce effects of temperature changes.

When the target frequency is changed, the coefficients c₀ to cₘ already stored in the memory can be used to perform the process of outputting the control signal (S704 and S705) without performing the process of obtaining the coefficients c₀ to cₘ (S701 to S703) again. As a result, when the target frequency is changed, the oscillation frequency can rapidly be changed to the target frequency.

An embodiment of the present invention has been described. As described above, the least-square method can be used to rapidly determine the value of the control signal corresponding to the target frequency. Specifically, if the approximate curve showing the frequency characteristic of the oscillation circuit is the mth order, the coefficients c₀ to cₘ are calculated by sampling for m+1 times to determine the value of the control signal corresponding to the target frequency based on the calculated coefficients c₀ to cₘ. For example, if the order of the approximate curve of the frequency characteristic is the second order, while the value of the control signal must be changed up to 255 times in the method of changing the value of the control signal stepwise within the variable range, the value of the control signal corresponding to the target frequency can be determined in this embodiment by changing the value of the control signal only three times.

The coefficients c₀ to cₘ can be obtained every time the target frequency is changed to reduce effects of temperature changes.

When the target frequency is changed, the oscillation frequency can rapidly be changed to the target frequency by using the coefficients c₀ to cₘ already stored in the memory to determine the value of the control signal.

By determining the value of the control signal setting the tuning frequency of the high-frequency tuning circuit 11 to the target frequency in accordance with the process shown in FIG. 7, the signal having the reception frequency can quickly be extracted from the FM reception signals received from the antenna 10. Since a PLL circuit is not necessary for adjusting the tuning frequency, a circuit scale can be reduced.

Similarly, by determining the value of the control signal setting the oscillation frequency of the local oscillation circuit 13 to the target frequency in accordance with the process shown in FIG. 7, the oscillation signal necessary for generating the intermediate frequency signal can quickly be generated. Since a PLL circuit is not necessary for adjusting the oscillation frequency, a circuit scale can be reduced.

By determining the value of the control signal setting the oscillation frequency of the oscillation circuit 18 to the target frequency in accordance with the process shown in FIG. 7, the oscillation signal necessary for the stereo demodulation process can quickly be generated. Since a PLL circuit is not necessary for adjusting the oscillation frequency, a circuit scale can be reduced.

The above embodiments of the present invention are simply for facilitating the understanding of the present invention and are not in any way to be construed as limiting the present invention. The present invention may variously be changed or altered without departing from its spirit and encompass equivalents thereof.

Although the adjustment of the oscillation frequency of the oscillation circuit included in, for example, the FM radio receiver 1 has been described in an embodiment, the oscillation frequency can also be adjusted in an oscillation circuit included in an AM radio receiver as is the case with this embodiment. Although the control signal is, for example, eight bits in an embodiment, the control signal may be other than eight bits.

It is claimed:

1. An oscillation controlling apparatus configured to control an oscillation frequency of an oscillation circuit to be a target frequency, comprising:
a frequency acquiring unit configured to acquire a plurality of oscillation frequencies of the oscillation circuit for a plurality of values of control signals by outputting the plurality of control signals increasing or decreasing the oscillation frequency of the oscillation circuit as values thereof are increased or decreased;
a frequency characteristic calculating unit configured to calculate data indicating a relationship between the plurality of oscillation frequencies and the plurality of values of the control signals with a least-square method, based on the plurality of values of the control signals output by the frequency acquiring unit and the plurality of oscillation frequencies acquired by the frequency acquiring unit; and
a control signal output unit configured to output the control signal setting the oscillation frequency to the target frequency, based on the data calculated by the frequency characteristic calculating unit.

2. The oscillation controlling apparatus of claim 1, wherein
every time the target frequency is changed,
the frequency acquiring unit is configured to output the plurality of values of the control signals to acquire the plurality of oscillation frequencies of the oscillation circuit for the plurality of values of the control signals, and
the frequency characteristic calculating unit is configured to calculate the data with a least-square method, based on the plurality of values of the control signals output by the frequency acquiring unit and the plurality of oscillation frequencies acquired by the frequency acquiring unit.

3. The oscillation controlling apparatus of claim 1, wherein
the data is stored in a predetermined memory, and wherein
when the target frequency is changed, the control signal output unit is configured to output the control signal setting the oscillation frequency to the changed target frequency based on the data stored in the memory.

4. The oscillation controlling apparatus of claim 1, wherein
the oscillation circuit is a tuning circuit configured to extract a signal having the target frequency from FM reception signals or AM reception signals.

5. The oscillation controlling apparatus of claim 2, wherein
the oscillation circuit is a tuning circuit configured to extract a signal having the target frequency from FM reception signals or AM reception signals.

6. The oscillation controlling apparatus of claim 3, wherein
the oscillation circuit is a tuning circuit configured to extract a signal having the target frequency from FM reception signals or AM reception signals.

7. The oscillation controlling apparatus of claim 1, wherein
the oscillation circuit is a local oscillation circuit configured to output a signal having the target frequency corresponding to a reception frequency, which is mixed with a signal having the reception frequency extracted from FM reception signals or AM reception signals to generate an intermediate frequency signal.

8. The oscillation controlling apparatus of claim 2, wherein
the oscillation circuit is a local oscillation circuit configured to output a signal having the target frequency corresponding to a reception frequency, which is mixed with a signal having the reception frequency extracted from FM reception signals or AM reception signals to generate an intermediate frequency signal.

9. The oscillation controlling apparatus of claim 3, wherein
the oscillation circuit is a local oscillation circuit configured to output a signal having the target frequency corresponding to a reception frequency, which is mixed with a signal having the reception frequency extracted from FM reception signals or AM reception signals to generate an intermediate frequency signal.

10. The oscillation controlling apparatus of claim 1, wherein
the oscillation circuit is configured to output a signal having the target frequency corresponding to a pilot signal included in a FM-detected stereo composite signal to generate right and left audio signals from the FM-detected stereo composite signal.

11. The oscillation controlling apparatus of claim 2, wherein
the oscillation circuit is configured to output a signal having the target frequency corresponding to a pilot signal included in a FM-detected stereo composite signal to generate right and left audio signals from the FM-detected stereo composite signal.

12. The oscillation controlling apparatus of claim 3, wherein
the oscillation circuit is configured to output a signal having the target frequency corresponding to a pilot signal included in a FM-detected stereo composite signal to generate right and left audio signals from the FM-detected stereo composite signal.

13. A recording medium having recorded thereon a program of controlling an oscillation frequency of an oscillation circuit to be a target frequency, the program driving a processor to execute the steps of:
acquiring a plurality of oscillation frequencies of the oscillation circuit for a plurality of values of control signals by outputting the plurality of control signals increasing or decreasing the oscillation frequency of the oscillation circuit as values thereof are increased or decreased;
calculating data indicating a relationship between the plurality of oscillation frequencies and the plurality of values of the control signals with a least-square method, based on the plurality of values of the control signals output and the plurality of oscillation frequencies acquired; and
outputting the control signal setting the oscillation frequency to the target frequency based on the calculated data.

14. The recording medium having the program recorded thereon of claim 13, wherein
the oscillation circuit is a tuning circuit configured to extract a signal having the target frequency from FM reception signals or AM reception signals.

15. The recording medium having the program recorded thereon of claim 13, wherein
the oscillation circuit is a local oscillation circuit configured to output a signal having the target frequency corresponding to a reception frequency, which is mixed with a signal having the reception frequency extracted from FM reception signals or AM reception signals to generate an intermediate frequency signal.

16. The recording medium having the program recorded thereon of claim 13, wherein
the oscillation circuit is configured to output a signal having the target frequency corresponding to a pilot signal included in a FM-detected stereo composite signal to generate right and left audio signals from the FM-detected stereo composite signal.

17. A channel selecting apparatus comprising:
a tuning circuit configured to oscillate at an oscillation frequency corresponding to an input control signal to extract a signal having the oscillation frequency from FM reception signals or AM reception signals; and
an oscillation controlling apparatus configured to control the oscillation frequency of the tuning circuit to be a reception frequency,
the oscillation controlling apparatus including
a frequency acquiring unit configured to acquire a plurality of oscillation frequencies of the oscillation circuit for a plurality of values of the control signals by outputting the plurality of control signals increasing or decreasing the oscillation frequency of the oscillation circuit as values thereof are increased or decreased;
a frequency characteristic calculating unit configured to calculate a first data indicating a relationship between the plurality of oscillation frequencies of the tuning circuit and the plurality of values of the control signals with a least-square method, based on the plurality of values of the control signals output by the frequency acquiring unit and the plurality of oscillation frequencies acquired by the frequency acquiring unit; and
a control signal output unit configured to output the control signal setting the oscillation frequency of the tuning circuit to the reception frequency, based on the first data calculated by the frequency characteristic calculating unit.

18. The channel selecting apparatus of claim 17, further comprising:
a local oscillation circuit configured to output a local oscillation signal having an oscillation frequency corresponding to the input control signal; and
a mixing circuit configured to mix the signal having the reception frequency output from the tuning circuit and the local oscillation signal corresponding to the reception frequency output from the local oscillation circuit to generate an intermediate frequency signal, wherein
the frequency acquiring unit is configured to acquire a plurality of oscillation frequencies of the local oscillation circuit for the plurality of values of the control signals by outputting the plurality of values of the control signals, wherein
the frequency characteristic calculating unit is configured to calculate a second data indicating a relationship between the plurality of oscillation frequencies of the local oscillation circuit and the plurality of values of the control signals with a least-square method, based on the plurality of values of the control signals output by the frequency acquiring unit and a plurality of oscillation frequencies acquired by the frequency acquiring unit, and wherein
the control signal output unit is configured to output the control signal setting the oscillation frequency of the local oscillation circuit to the reception frequency, based on the second data calculated by the frequency characteristic calculating unit.

19. The channel selecting apparatus of claim 18, further comprising:
an FM detection circuit configured to perform FM detection of the intermediate frequency signal to output a stereo composite signal;
an oscillation circuit configured to output a signal having an oscillation frequency corresponding to the input control signal; and
a stereo demodulation circuit configured to generate right and left audio signals based on the stereo composite signal output from the FM detection circuit and the signal output from the oscillation circuit, which has a frequency corresponding to a frequency of a pilot signal included in the stereo composite signal, wherein
the frequency acquiring unit is configured to acquire a plurality of oscillation frequencies of the oscillation circuit for the plurality of values of the control signals by outputting the plurality of values of the control signals, wherein
the frequency characteristic calculating unit is configured to calculate a third data indicating a relationship between the plurality of oscillation frequencies of the oscillation circuit and the plurality of value of the control signals with a least-square method, based on the plurality of values of the control signals output by the frequency acquiring unit and the plurality of the oscillation frequencies acquired by the frequency acquiring unit, and wherein
the control signal output unit is configured to output the control signal setting the oscillation frequency of the local oscillation circuit to a frequency corresponding to the frequency of the pilot signal, based on the third data calculated by the frequency characteristic calculating unit.
